(19) United States
(12) Patent Application Publication
(10) Pub. No.: US 2024/0317083 A1
(43) Pub. Date: Sep. 26, 2024

(54) CONNECTOR

(71) Applicant: Yazaki Corporation, Tokyo (JP)

(72) Inventors: Yasuhiro YAMAGUCHI, Kakegawa-shi (JP); Hideki Mizuno, Kakegawa-shi (JP); Shinsuke Aoshima, Fujieda-shi (JP)

(73) Assignee: Yazaki Corporation, Tokyo (JP)

(21) Appl. No.: 18/605,262

(22) Filed: Mar. 14, 2024

(30) Foreign Application Priority Data
Mar. 20, 2023 (JP) 2023-044221

(51) Int. Cl. B60L 53/16; H01R 13/621; H01R 103/00; H05K 7/20

(52) U.S. Cl. CPC B60L 53/16; H01R 13/6215; H05K 7/20854; H01R 2103/00; H01R 2201/26

(57) ABSTRACT

A connector includes a terminal including a female threaded portion at one end side of the terminal and a female mating portion at an opposite end side of the terminal; a ring terminal connected to an end of an electric wire, the ring terminal being placed over one end of the terminal; a heat storage material element placed over the ring terminal; a bolt which is screwed in the female threaded portion while being inserted through a bolt insertion hole in the heat storage material element and a bolt insertion hole in the ring terminal to fasten the terminal, the ring terminal and the heat storage material element together, and a housing accommodating the terminal, the ring terminal, the heat storage material element and the bolt.

### BACKGROUND OF THE INVENTION

### Technical Field

The present invention relates to a connector.

### Background Art

A connector is mounted to a vehicle body such as an electric vehicle body or hybrid vehicle body for charging a battery mounted to the vehicle body (see e.g. Patent Document 1). This connector is configured to be mated with a charging plug installed e.g. in a charging stand, and includes one or more terminals and a housing, wherein the one or more terminals are connected to an end(s) of one or more electric wires. Such a connector may be referred to as a “charging inlet”.

### CITATION LIST

### Patent Literature

Patent Document 1: JP 2020-077573 A

### SUMMARY OF THE INVENTION

For connectors as mentioned above, a connector current is increasing due to increase in battery capacity and/or needs for reduction in a charging time, which results in a problem that a temperature of the terminal is abruptly increased during charging due to heat generation in a portion with a high resistance such as contacts for a charging plug and/or connecting portion for the electric wire.

Therefore, an objective of the present invention is to provide a connector which enables increase in a temperature of a terminal to be suppressed.

The present invention relates to a connector including: a terminal including a female threaded portion at one end side of the terminal; a ring terminal connected to an end of an electric wire, the ring terminal being placed over one end of the terminal; a heat storage material element placed over the ring terminal; a bolt which is screwed in the female threaded portion while being inserted through a bolt insertion hole in the heat storage material element and a bolt insertion hole in the ring terminal to fasten the terminal, the ring terminal and the heat storage material element together; and a housing accommodating the terminal, the ring terminal, the heat storage material element and the bolt.

The present invention enables increase in a temperature of the terminal to be suppressed.

### BRIEF DESCRIPTION OF THE DRAWINGS

FIG. 1 shows a perspective view of a connector according to a first embodiment of the present invention;

FIG. 2 shows a front view of the connector according to FIG. 1;

FIG. 3 shows a sectional view along the line A-A as shown in FIG. 2;

FIG. 4 shows a perspective view of a connector according to a second embodiment of the present invention;

FIG. 5 shows a side view of the connector according to FIG. 4; and

FIG. 6 shows a sectional view along the line B-B as shown in FIG. 5.

### DETAILED DESCRIPTION OF THE PREFERRED EMBODIMENTS

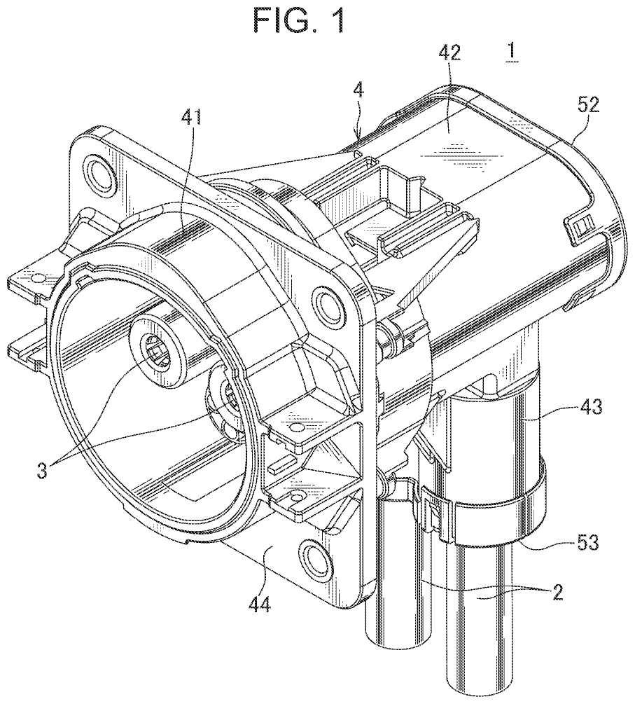

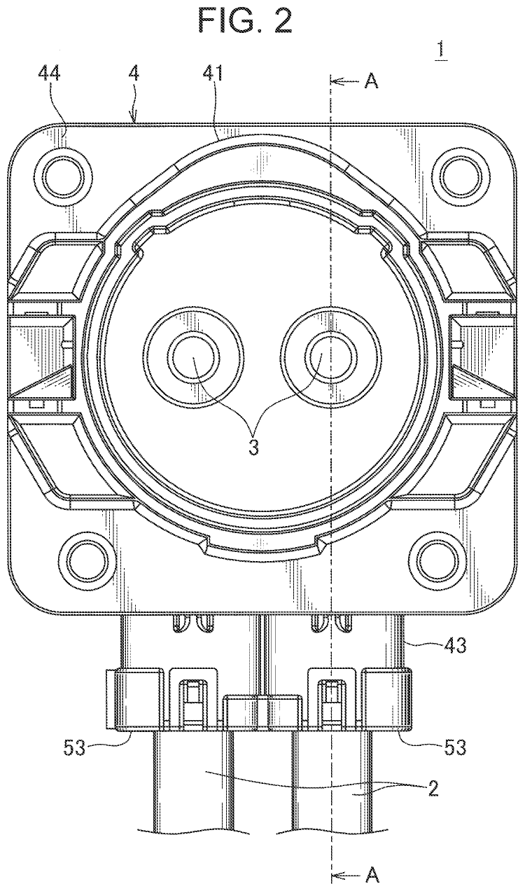

A “connector” according to a first embodiment of the present invention will be described with reference to FIGS. 1 to 3.

A connector 1 as shown in FIGS. 1 to 3 is intended to be mounted to a vehicle body such as an electric vehicle body or hybrid vehicle body and mated with a charging plug installed e.g. in a charging stand in order to charge a vehicle onboard battery. The connector 1 may be referred to as a “charging inlet”.

The connector 1 includes terminals 3, ring terminals 6 connected to ends of electric wires 2, heat storage material elements 7 placed over the ring terminals 6, bolts 9, a housing 4 accommodating these components, rubber plugs 51 and holders 52 and 53.

The connector 1 in the present example is connected to two electric wires 2. Accordingly, the connector 1 includes two terminals 3, two ring terminals 6, two heat storage material elements 7 and two bolts 9. The two terminals 3, two ring terminals 6, two heat storage material elements 7, and two bolts 9 are identical components.

Each of the rubber plugs 51 is configured to be attached to an outer circumference of the electric wire 2 to provide seal between an inner surface of the housing 4 and an outer surface of the electric wire 2. Each of the holders 53 serves for preventing the rubber plug 51 from being removed from the housing 4. Thus, the connector 1 is sealed with the rubber plugs 51, and therefore tends to cause heat to be accumulated within the housing 4.

Each of the electric wires 2 is a circular electric wire including a core wire 21 and an insulating coating 22. The insulating coating 22 is removed at the end of the electric wire 2 to expose the core wire 21. An electric wire connecting portion 62 of the ring terminal 6 is electrically connected to this exposed portion of the core wire 21.

Each of the terminal 3 includes a female threaded portion 32 formed at one end side of the terminal 3 and a female mating portion 31 formed at an opposite end side of the terminal 3. The female threaded portion 32 includes a hole 33 and a thread, the hole 33 being formed concavely from one end of the terminal 3, wherein the thread is formed in a spiral shape on an inner circumferential surface of the hole 33. The female threaded portion 32 is configured for screwing the bolt 9 therein. The mating portion 31 is mated with a partner terminal provided at the charging plug.

Each of the ring terminals 6 is formed in a plate shape and includes a connecting portion 61 and the electric wire connecting portion 62, wherein a bolt insertion hole 61a is formed in the connecting portion 61 at its center. The connecting portion 61 is placed over one end of the terminal 3 to be electrically connected to the terminal 3. The ring terminal 6 may be referred to as a “LA terminal”.

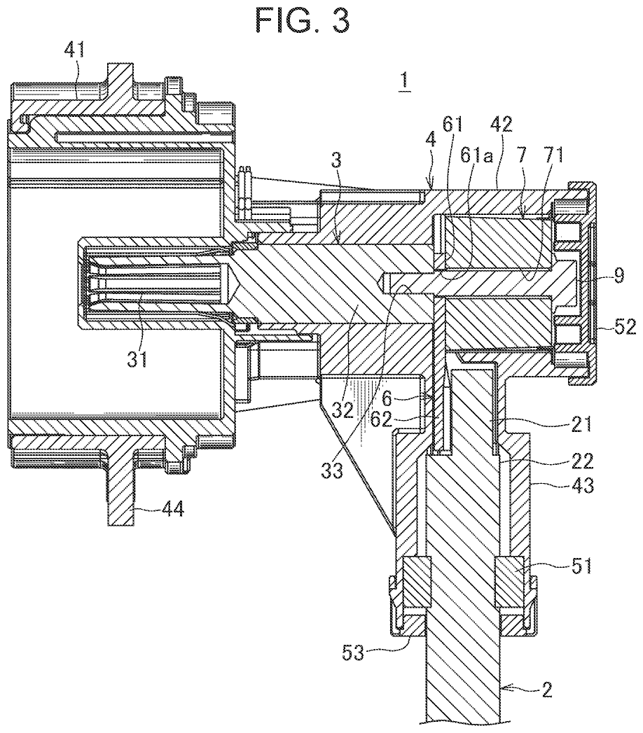

As shown in FIG. 3, each of the heat storage material elements 7 is formed in a block shape and includes a planar surface, wherein the planar surface is placed over the connecting portion 61 of the ring terminal 6. Furthermore, a bolt insertion hole 71 is formed in the heat storage material element 7. The connecting portion 61 is clamped between the heat storage material element 7 and the terminal 3.

Each of the bolts 9 is screwed in the female threaded portion 32 of the terminal 3 while being inserted through the bolt insertion hole 71 in the heat storage material element 7 and the bolt insertion hole 61a in the ring terminal 6 to fasten the terminal 3, the ring terminal 6 and the heat storage material element 7 together.

The housing 4 is made of a resin and includes a first accommodating section 41, a second accommodating section 42, a third accommodating section 43 and a flange section 44.

The mating portions 31 of the terminals 3 are accommodated in the first accommodating section 41. The first accommodating section 41 is configured to receive the charging plug.

The second accommodating section 42 is adjacent to the first accommodating section 41. The female threaded portions 32 of the terminals 3, the connecting portions 61 of the ring terminals 6, the heat storage material elements 7 and the bolts 9 are accommodated in the second accommodating section 42. The second accommodating section 42 is opened on a side of the second accommodating section 42 facing away from the first accommodating section 41, wherein this opening of the second accommodating section 42 is closed by the holder 52.

The third accommodating section 43 is adjacent to the second accommodating section 42. The electric wire connecting portions 62 of the ring terminals 6, the ends of the electric wires 2, and the rubber plugs 51 are accommodated in the third accommodating section 43. The third accommodating section 43 is opened on a side of the third accommodating section 43 facing away from the second accommodating section 42, wherein this opening of the third accommodating section 43 is closed by rubber plug 51 and the holder 53. As shown in FIG. 3, the first accommodating section 41, second accommodating section 42 and third accommodating section 43 are connected in a L-shape.

The flange section 44 extends outwardly from an outer circumferential surface of the first accommodating section 41. The flange section 44 is fixed to a vehicle body by means of one or more bolts.

When such a connector 1 is mated with the charging plug and charging is started, heat is generated e.g. in the mating portions 31 of the terminals 3 which have a high resistance. However, this heat is stored in the heat storage material elements 7 via the ring terminals 6 so that increase in a temperature of the terminals 3 is suppressed and an increasing rate of the temperature of the terminals 3 is reduced. Since the heat storage material elements 7 allow the increase in the temperature of the terminals 3 to be suppressed in the above-described manner, it is possible to avoid an additional cooling structure and/or increase in a diameter of the electric wires 2, which enables increase in costs and/or weight of the connector 1 to be avoided. Furthermore, the terminals 3, ring terminals 6 and heat storage material elements 7 are fastened together by the bolts 9, which may ensure a surface pressure between these components by means of an axial force of the bolts 9. This enables an interface thermal resistance to be reduced to improve a heat transfer characteristic from the terminals 3 to the heat storage material elements 7.

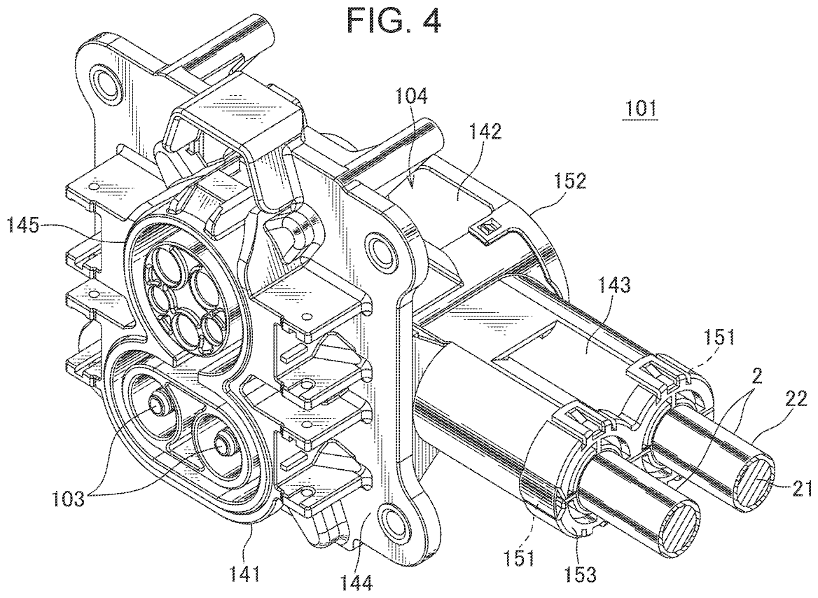

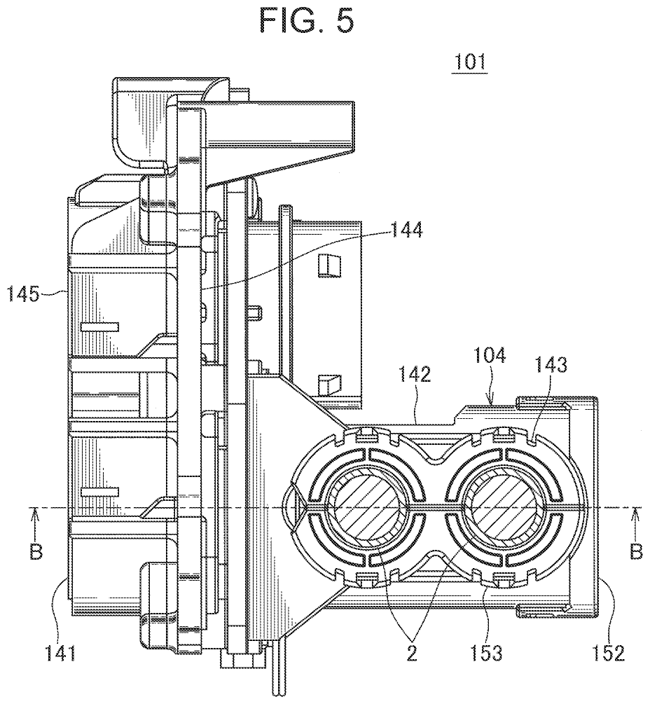

A “connector” according to a second embodiment of the present invention will be described with reference to FIGS. 4 to 6. In FIGS. 4 to 6, same reference signs designate same features as those of the first embodiment, wherein description of such features is omitted.

Similarly to the first embodiment, a connector 101 as shown in FIGS. 4 to 6 is intended to be mounted to a vehicle body such as an electric vehicle body or hybrid vehicle body and mated with a charging plug installed e.g. in a charging stand in order to charge a vehicle onboard battery.

The connector 101 includes two terminals 103, two ring terminals 6, two heat storage material elements 7, 107, three bolts 9, 19, 109, nuts 18, one busbar 8, a housing 104 accommodating these components, rubber plugs 151 and holders 152 and 153.

Similarly, the connector 101 according to the present example is connected to two electric wires 2, wherein the rubber plugs 151 are attached to respective outer circumferences of the electric wires 2. Each of the rubber plugs 151 provides seal between an inner surface of the housing 104 and an outer surface of the electric wire 2. Each of the holders 153 prevents the rubber plug 151 from being removed from the housing 104.

Each of the terminal 103 includes a female threaded portion 132 formed at one end side of the terminal 103 and a male mating portion 131 formed at an opposite end side of the terminal 103. The female threaded portion 132 includes a hole 133 and a thread, the hole 133 being formed concavely from one end of the terminal 103, wherein the thread is formed in a spiral shape on an inner circumferential surface of the hole 133. The female threaded portion 132 of one of the terminals 103 is configured for screwing the bolt 9 therein. The female threaded portion 132 of the other of the terminals 103 (which corresponds to a “second terminal”) is configured for screwing the bolt 109 (which corresponds to a “second bolt”) therein. The mating portion 131 is mated with a partner terminal provided at the charging plug.

The ring terminals 6 are connected to the ends of the electric wires 2. A connecting portion 61 of one of the ring terminals 6 is placed over one end of one of the terminals 103 to be electrically connected to the terminal 103. Furthermore, the heat storage material element 7 is placed over this connecting portion 61, wherein the terminal 103, ring terminal 6 and heat storage material element 7 are fastened together by the bolt 9. The busbar 8 is connected to a connecting portion 61 of the other of the ring terminals 6 (which corresponds to a “second ring terminal”).

The busbar 8 is formed by bending a metal plate in a S-shape and includes a first connecting portion 81 and a second connecting portion 82, wherein the first connecting portion 81 is placed over the connecting portion 61 of the other ring terminal 6 and, and the second connecting portion 82 is placed over on one end of the other terminal 103.

The first connecting portion 81 includes a bolt insertion hole 81a formed therein. A bolt 19 is inserted through a bolt insertion hole 61a in the connecting portion 61 and the insertion hole 81a in the first connecting portion 81, wherein a nut 18 is screwed to the bolt 19 to fasten the connecting portion 61 and the first connecting portion 81 together.

The second connecting portion 82 includes a bolt insertion hole 82a formed therein. A heat storage material elements 107 (which corresponds to a “second heat storage material elements”) is placed over this second connecting portion 82.

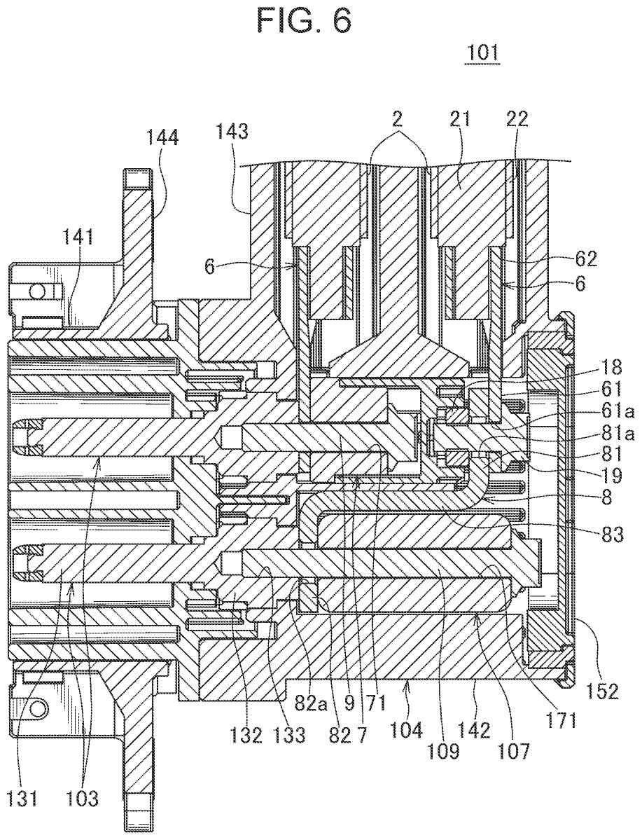

As shown in FIG. 6, the heat storage material element 107 is formed in a block shape and includes a planar surface, wherein the planar surface is placed over the second connecting portion 82 of the busbar 8. Furthermore, a bolt insertion hole 171 is formed in the heat storage material element 107. The second connecting portion 82 is clamped between the heat storage material element 107 and the other terminal 103.

Each of the bolts 109 is screwed in the female threaded portion 132 of the other terminal 103 while being inserted through the bolt insertion hole 171 in the heat storage material element 107 and the bolt insertion hole 82a in the second connecting portion 82 to fasten the terminal 103, the busbar 8 and the heat storage material element 107 together.

The housing 104 is made of a resin and includes a first accommodating section 141, a second accommodating section 142, a third accommodating section 143, a flange section 144, and a five-pole terminal accommodating section 145. The five-pole terminal accommodating section 145 is configured to be mated with a charging plug according to a specification which is different from that for the present example, and is not used in the present example.

The mating portions 131 of the terminals 103 are accommodated in the first accommodating section 141. The first accommodating section 141 is configured to receive the charging plug.

The second accommodating section 142 is adjacent to the first accommodating section 141. The female threaded portions 132 of the terminals 103, the connecting portions 61 of the ring terminals 6, the heat storage material elements 7, 107, the bolts 9, 109 and the busbar 8 and possibly other components are accommodated in the second accommodating section 142. The second accommodating section 142 is opened on a side of the second accommodating section 142 facing away from the first accommodating section 141, wherein this opening of the second accommodating section 142 is closed by the holder 152.

The third accommodating section 143 is adjacent to the second accommodating section 142. The electric wire connecting portions 62 of the ring terminals 6, the ends of the electric wires 2, and the rubber plugs 151 are accommodated in the third accommodating section 143. The third accommodating section 143 is opened on a side of the third accommodating section 143 facing away from the second accommodating section 142, wherein this opening of the third accommodating section 43 is closed by the rubber plug 151 and the holder 153. As shown in FIG. 6, the first accommodating section 141, second accommodating section 142 and third accommodating section 143 are connected in a L-shape.

The flange section 144 extends outwardly from outer circumferential surfaces of the first accommodating section 141 and five-pole terminal accommodating section 145. The flange section 144 is fixed to a vehicle body by means of one or more bolts.

The two terminals 103 are arranged in parallel to each other. Similarly, the two ring terminals 6 are arranged in parallel to each other, and the two bolts 9 and 109 are arranged in parallel to each other. The two terminals 103, the two ring terminals 6 and the two bolts 9 and 109 are arranged on the same plane. As shown in FIG. 6, the inner terminal 103 and ring terminal 6 are electrically connected directly to each other, while the outer terminal 103 and ring terminal 6 cannot be electrically connected directly to each other. Therefore, the outer terminal 103 and ring terminal 6 are electrically to each other via the busbar 8.

There is a large space outside the busbar 8 (on a side of the busbar 8 opposite to the heat storage material elements 7). Therefore, the heat storage material elements 107 which is arranged in the space has a larger volume than the heat storage material elements 7. For this reason, the heat storage material element 7 is made of a material having a smaller volume but a higher heat capacity per unit volume than those of a material of the heat storage material element 107. Thus, the heat storage material elements 7 can ensure a heat capacity which is comparable with that of the heat storage material elements 107.

When such a connector 101 is mated with the charging plug and charging is started, heat is generated e.g. in the mating portions 131 of the terminals 103 which have a high resistance. For the one terminal 103, this heat is stored in the heat storage material elements 7 via the ring terminal 6 so that increase in a temperature of the terminal 103 is suppressed and an increasing rate of the temperature of the terminal 103 is reduced. For the other terminal 103, this heat is stored in the heat storage material elements 107 via the busbar 8 so that increase in a temperature of the terminal 103 is suppressed and an increasing rate of the temperature of the terminal 103 is reduced.

Since the heat storage material elements 7, 107 allow the increase in the temperature of the terminals 103 to be suppressed in the above-described manner, it is possible to avoid an additional cooling structure and/or increase in a diameter of the electric wires 2, which enables increase in costs and/or weight of the connector 101 to be avoided. Furthermore, the terminal 103, ring terminal 6 and heat storage material elements 7 is fastened together by the bolt 9, which may ensure a surface pressure between these components by means of an axial force of the bolt 9. This enables an interface thermal resistance to be reduced to improve a heat transfer characteristic from the terminal 103 to the heat storage material element 7. Similarly, the terminal 103, busbar 8 and heat storage material element 107 are fastened together by the bolt 109, which may ensure a surface pressure between these components by means of an axial force of the bolt 109. This enables an interface thermal resistance to be reduced to improve a heat transfer characteristic from the terminal 103 to the heat storage material element 107.

It is to be noted that the embodiments as described above merely illustrate representative examples for the present invention, and the present invention is not limited to these embodiments. I.e., various modifications may be performed without departing from the core of the present invention. It is obvious that such modifications are included in the scope of the present invention as far as the modifications comprise the features of the present invention.

### REFERENCE SIGNS LIST

1, 101 Connector
2 Electric wires
3, 103 Terminals
4, 104 Housing
6 Ring terminal
7, 107 Heat storage material elements
9, 109 Bolts

What is claimed is:

1. A connector comprising:
a terminal including a female threaded portion at one end side of the terminal;
a ring terminal connected to an end of an electric wire, the ring terminal being placed over one end of the terminal;
a heat storage material element placed over the ring terminal;
a bolt which is screwed in the female threaded portion while being inserted through a bolt insertion hole in the heat storage material element and a bolt insertion hole in the ring terminal to fasten the terminal, the ring terminal and the heat storage material element together; and
a housing accommodating the terminal, the ring terminal, the heat storage material element and the bolt.

2. The connector according to claim 1, further comprising:
a second terminal including a female threaded portion at one end side of the second terminal;
a second ring terminal connected to an end of an electric wire;
a busbar connected to the second ring terminal, the busbar being placed over one end of the second terminal;
a second heat storage material element placed over the busbar; and
a second bolt which is screwed in the female threaded portion while being inserted through a bolt insertion hole in the second heat storage material element and a bolt insertion hole in the busbar to fasten the second terminal, the busbar and the second heat storage material element together.

3. The connector according to claim 2,
wherein the heat storage material element is made of a material having a smaller volume and a higher heat capacity per unit volume than those of a material of the second heat storage material element.
